(19) United States
(12) Patent Application Publication
(10) Pub. No.: US 2013/0039130 A1
(43) Pub. Date: Feb. 14, 2013

(54) PROGRAM METHOD OF NONVOLATILE MEMORY DEVICE

(71) Applicant: Ji-Sang Lee, Iksan-si (KR)

(72) Inventor: Ji-Sang Lee, Iksan-si (KR)

(21) Appl. No.: 13/568,287

(22) Filed: Aug. 7, 2012

(30) Foreign Application Priority Data
Aug. 8, 2011 (KR) 10-2011-0078654

(51) Int. Cl. G11C 16/10

(52) U.S. Cl. 365/185.19; 365/185.22

(57) ABSTRACT

Disclosed is a program method of a nonvolatile memory device including applying a first program voltage to a word line of a memory cell; verifying a variation of a threshold voltage of the memory cell; and applying a second program voltage to a memory cell having a threshold voltage higher than a reference level, the second program voltage being lower in level than the first voltage pulse.

### CROSS-REFERENCE TO RELATED APPLICATIONS

This application claims the benefits, under 35 U.S.C. §119, of Korean Patent Application No. 10-2011-0078654 filed Aug. 8, 2011, the entirety of which is incorporated by reference herein.

### BACKGROUND

Example embodiments relate to a semiconductor memory device, and more particularly, relate to a program method of a nonvolatile memory device.

Semiconductor memory devices may be roughly classified into volatile semiconductor memory devices and nonvolatile semiconductor memory devices. The volatile semiconductor memory devices can perform read and write operations in a high speed, while contents stored therein may be lost at power-off. The nonvolatile semiconductor memory devices may retain contents stored therein even at power-off. The nonvolatile semiconductor memory devices may be used to store contents which must be retained regardless of whether they are powered.

The nonvolatile semiconductor memory devices may include a Mask Read-Only Memory (MROM), a Programmable ROM (PROM), an Erasable Programmable ROM (EPROM), an Electrically Erasable Programmable ROM (EEPROM), and the like.

A representative nonvolatile memory device may be a flash memory device. The flash memory device may be widely used as a voice and image data storing medium of information appliances such as a computer, a cellular phone, a PDA, a digital camera, a camcorder, a voice recorder, an MP3 player, a handheld PC, a game machine, a facsimile, a scanner, a printer, and the like.

In recent, a multi-bit memory device storing multi-bit data in one memory cell may be becoming increasingly common according to an increasing need for the integrity. It is desirable to manage a threshold voltage distribution of memory cells in order to improve the reliability of multi-level cells.

### SUMMARY

Some example embodiments provide a program method of a nonvolatile memory device.

In one embodiment, a program method of a nonvolatile memory device is disclosed. The method comprises applying a first program voltage to a word line of a memory cell; verifying a variation of a threshold voltage of the memory cell; and applying a second program voltage to a memory cell having a threshold voltage higher than a reference level, the second program voltage being lower in level than the first program voltage.

In another embodiment, a program method of a nonvolatile memory device is disclosed. The method comprises performing a plurality of program loops on memory cells in order to program the memory cells; applying a plurality of dual pulses to a word line of the memory cells, each of the plurality of dual pulses including a first pulse and a second pulse having a greater level than the first pulse such that the plurality of dual pulses includes a plurality of first pulses and a plurality of second pulses; during a period of at least one second pulse of the plurality of second pulses, applying a first bit line program voltage to a bit line coupled to a first memory cell of the memory cells if the first memory cell has a threshold voltage smaller than a first verify voltage, thereby programming the first memory cell; and during a period of at least one first pulse of the plurality of first pulses, applying a second bit line program voltage smaller than the first bit line program voltage to a bit line coupled to the first memory cell if the first memory cell has a threshold voltage greater than the first verify voltage and smaller than a second verify voltage, thereby programming the first memory cell.

In another embodiment, a method of programming a nonvolatile memory device is disclosed. The method comprises verifying a threshold voltage of first memory cells of the memory cells using a first verify voltage and a second verify voltage; applying a plurality of dual pulses to a selected word line of the first memory cells until programming the first memory cells to a particular program state among the plurality of program states completes, each of the plurality of dual pulses including a first pulse and a second pulse having a higher level than the first pulse and being incremented by a step voltage; during a period of at least one of second pulses of the plurality of dual pulses, applying a first bit line program voltage to bit lines coupled to a first set of memory cells of the first memory cells until a threshold voltage of the first set of memory cells reaches a level equal to or greater than the first verify voltage, the first set of memory cells having a threshold voltage smaller than the first verify voltage resulting from the verifying; and during a period of at least one of first pulses of the plurality of dual pulses, applying a second bit line program voltage smaller than the first bit line program voltage to bit lines coupled to a second set of memory cells of the first memory cells until a threshold voltage of the second set of memory cells reaches a level equal to or greater than the second verify voltage greater than the first verify voltage, the second set of memory cells having a threshold voltage greater than the first verify voltage and smaller than the second verify voltage resulting from the verifying.

### BRIEF DESCRIPTION OF THE FIGURES

Illustrative, non-limiting example embodiments will be more clearly understood from the following detailed description taken in conjunction with the accompanying drawings.

FIG. 1 is a block diagram schematically illustrating a nonvolatile memory device according to an example embodiment.

FIG. 2 is a waveform diagram illustrating voltages being supplied to a word line according to an example embodiment.

FIG. 3 is a diagram illustrating a 2-step verification operation according to an example embodiment.

FIG. 4 is a diagram for describing a dual pulse program manner and a 2-step verification manner according to an example embodiment.

FIG. 5 is a diagram illustrating a voltage condition of a dual pulse program and 2-step verification operation according to an example embodiment.

FIG. 6 is a flowchart for describing a program method according to an example embodiment.

FIGS. 7 through 9 are flowcharts for describing program method of target states according to some example embodiments.

FIG. 10 is a diagram illustrating a dual pulse program operation and a 2-step verification operation according to another embodiment.

FIG. 11 is a diagram illustrating a memory cell array in FIG. 1 according to an example embodiment.

FIG. 12 is a perspective view illustrating one of memory blocks in FIG. 11 according to an example embodiment.

FIG. 13 is a block diagram illustrating a user device including a solid state disk according to an example embodiment.

FIG. 14 is a block diagram illustrating a memory system according to another embodiment.

FIG. 15 is a block diagram illustrating a data storage device according to still another embodiment.

FIG. 16 is a diagram schematically illustrating a computing system including a flash memory device according to an example embodiment.

### DETAILED DESCRIPTION OF THE EMBODIMENTS

Various example embodiments will be described more fully hereinafter with reference to the accompanying drawings, in which some example embodiments are shown. This disclosure may, however, be embodied in many different forms and should not be construed as limited to the embodiments set forth herein. In the drawings, the size and relative sizes of circuitry and regions may be exaggerated for clarity. Like numbers refer to like elements throughout.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the disclosed embodiments.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which the disclosed embodiments belong. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

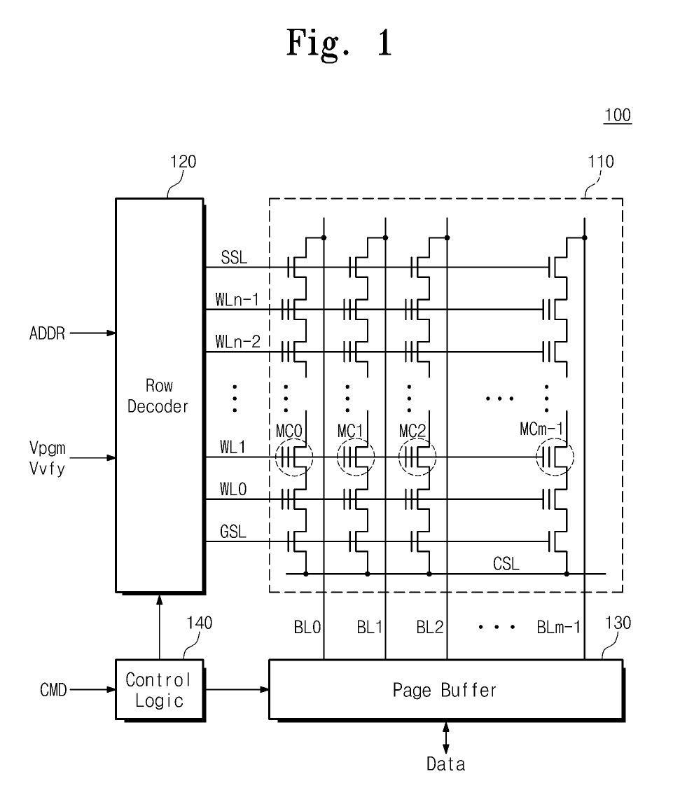

FIG. 1 is a block diagram schematically illustrating a nonvolatile memory device according to an example embodiment. Referring to FIG. 1, a nonvolatile memory device 100 may include a cell array 110, a row decoder 120, a page buffer 130, and control logic 140.

The cell array 110 may be connected with the row decoder 120 via word lines and selection lines SSL and GSL. The cell array 110 may be connected with the page buffer 130 via bit lines BL0 to BLm-1. The cell array 110 may include a plurality of NAND cell strings, each of which is connected with a bit line via string selection transistor SST.

A plurality of memory cells connected with the same word line may be programmed for the same program cycle or the same program loop. For example, memory cells MC0 to MCm-1 connected with a word line WL1 may be programmed to have the same state or different states for the same program cycle. In an embodiment, within one program cycle, the memory cell MC0 may be programmed to a program state P1, the memory cell MC1 to a program state P2, and the memory cells MC2 to MCm-1 to a program state P3.

In the disclosed embodiments, the nonvolatile memory device is assumed to be a multi-level flash memory device having multi-bit memory cells (e.g., 2-bit) capable of storing data bit values of 11, 01, 00, and 10 in relation to corresponding threshold voltage distributions. For example, a first threshold voltage distribution (e.g., E0) may be associated with an initial erase state (i.e., data value 11), a second threshold voltage distribution (e.g., P1) may be associated with the data value 01, a third threshold voltage distribution (e.g., P2) may be associated with the data value 00, and a fourth threshold voltage distribution (e.g., P3) may be associated with the data value 10.

With a program operation of the disclosed embodiments, although memory cells MC0 to MCm-1 are programmed to different target states, a difference between program end times may be reduced. Threshold voltage distributions corresponding to the target states P1, P2, and P3 may be managed tightly.

Channels of cell strings may be formed in a vertical or horizontal direction. The word lines of the cell array 110 can be stacked in a vertical direction. The cell array 110 may be formed to have the All Bit Line (ABL) architecture.

The row decoder 120 may select one of memory blocks of the cell array 110 in response to one or more addresses ADDR. The row decoder 120 may select one of word lines of the selected memory block. The row decoder 120 may transfer a word line voltage VWL from a voltage generator (not shown) to the selected word line of the selected memory block. In a program operation, the row decoder 120 may transfer a program voltage Vpgm to a selected word line and a pass voltage Vpass to unselected word lines.

In one embodiment, a plurality of program loops are performed on memory cells in order to program the memory cells. The program voltage Vpgm may include a plurality of dual pulses having a plurality of first pulses and a plurality of second pulses. For example, each of the plurality of dual pulses for the program voltage Vpgm may be applied to a selected word line for a period of each of the plurality of program loops, respectively.

In one embodiment, the program voltage Vpgm may be formed of at least two pulses having different levels for one program loop. This program operation may be referred to as a multi-pulse program operation. For example, such a program operation that two pulses are supplied for one program loop may be referred to as a dual pulse program operation. A verification voltage for each of the target states (e.g., P1, P2, and P3) may be provided following applying of a program pulse. In the dual pulse program operation, the row decoder 120 may be configured to provide program pulses of different levels to a selected word line continuously within one program loop.

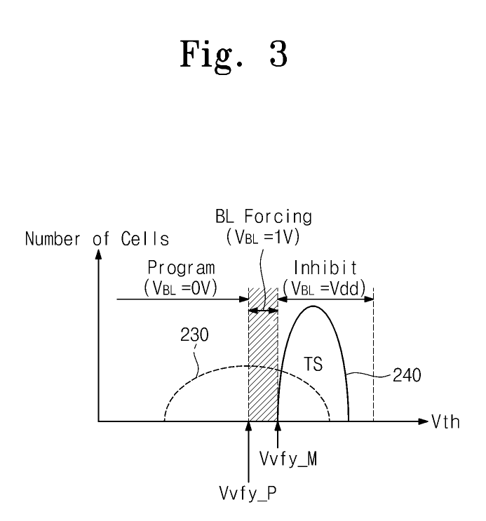

In one embodiment, a verification operation for one target state may be performed using two verification voltages. For example, a verification operation for one target state may be formed of a pre-verification operation and a main-verification operation. This verification operation may be referred to as a 2-step verification operation. The row decoder 120 may be configured to provide a selected word line with a program voltage in the dual pulse operation and with a verification voltage in the 2-step verification operation. The 2-step verification operation will be more fully described with reference to FIG. 3.

The page buffer 130 may operate as a write driver or a sense amplifier according to a mode of operation. In a program operation, the page buffer 130 may supply a bit line voltage corresponding to program data to a bit line of the cell array 110. In a read operation, the page buffer 130 may sense data stored in a selected memory cell via a bit line. The page buffer 130 may latch the sensed data to output it to an external device.

The page buffer 130 may supply a bit line voltage during a time when a plurality of program pulses is applied at one program loop. In the dual pulse program operation, the page buffer 130 may supply a bit line of a selected memory cell with 0V within a period where a program pulse is supplied to a word line of a selected memory cell. In this case, electrons may be injected in a high speed into a floating gate of the selected memory cell by the F-N tunneling. Accordingly, in a program operation, a threshold voltage may be shifted relatively largely.

In case of the dual pulse program operation, when a program pulse is applied to a selected word line, the page buffer 130 may supply a forcing voltage (e.g., 1V) to a bit line of the selected memory cell. In this case, a relatively less amount of electrons may be injected into a floating gate of the selected memory cell. Accordingly, a threshold voltage of a memory cell may be shifted by a relatively less amount. In one embodiment, the forcing voltage may include various voltage levels, e.g., 0.8V, 0.9V, 1.2V, among other voltage levels.

In the dual pulse program operation, the page buffer 130 may supply an inhibition voltage (e.g., Vdd) to a bit line of a selected memory cell within a period where a program pulse is supplied to a word line of the selected memory cell. In this case, a string selection transistor SST connected with a bit line may be shut off, and a channel of the selected memory cell may be floated. A potential of the floated channel may be boosted by the coupling due to the program pulse. A potential difference between a channel and a gate of the selected memory cell may be insufficient to generate the F-N tunneling. As a result, the selected memory cell may be program inhibited.

In the dual pulse program operation, the page buffer 130 according to an example embodiment may provide a bit line voltage to a memory cell having a specific target state (e.g., P2) according to the control of the control logic 140. The control logic 140 may include a plurality of control circuits. The page buffer 130 may provide a bit line forcing voltage to a bit line when a threshold voltage of a memory cell to be programmed to the specific target state is below a first verification level. The page buffer 130 may provide 0V to a bit line when a threshold voltage of a memory cell to be programmed to the specific target state is higher than the first verification level. The page buffer 130 may provide a program inhibition voltage Vdd to a bit line when a threshold voltage of a memory cell to be programmed to the specific target state P2 is higher than a second verification level.

The control logic 140 may control the row decoder 120 and the page buffer 130 so as to a dual pulse program operation and a 2-step verification operation in response to a command CMD. In a case where dual pulse programming is executed, it is not easy to apply the 2-step verification operation to memory cells programmed to a specific target state (e.g., P2). However, the control logic 140 may enable the 2-step verification operation to be applied to memory cells programmed to the specific target state during the dual pulse program operation. Accordingly, a distribution of threshold voltages of programmed memory cells may be improved, and a read margin may be secured. A detailed control method of the control logic 140 will be more fully described later.

Although not illustrated, the nonvolatile memory device 100 may further comprise a voltage generator for providing a program voltage Vpgm and a verification voltage Vvfy. The voltage generator may generate an Incremental Step Pulse Programming (ISPP) program voltage Vpgm which is supplied to a word line of selected memory cells in a dual pulse operation. The program voltage Vpgm includes a plurality of dual pulses having a plurality of first pulses and a plurality of second pulses. In one embodiment, each of the plurality of first pulses and the plurality of second pulses includes a voltage level increasing by a 0.2V step voltage. This step voltage may include various step voltages, e.g., 0.1V, 0.3V, among other step voltages. The voltage generator may generate two verification voltages having different levels with respect to each target state.

With the above description, the nonvolatile memory device 100 may apply the 2-step verification operation regardless of a target state of a selected memory cell at a dual pulse program operation.

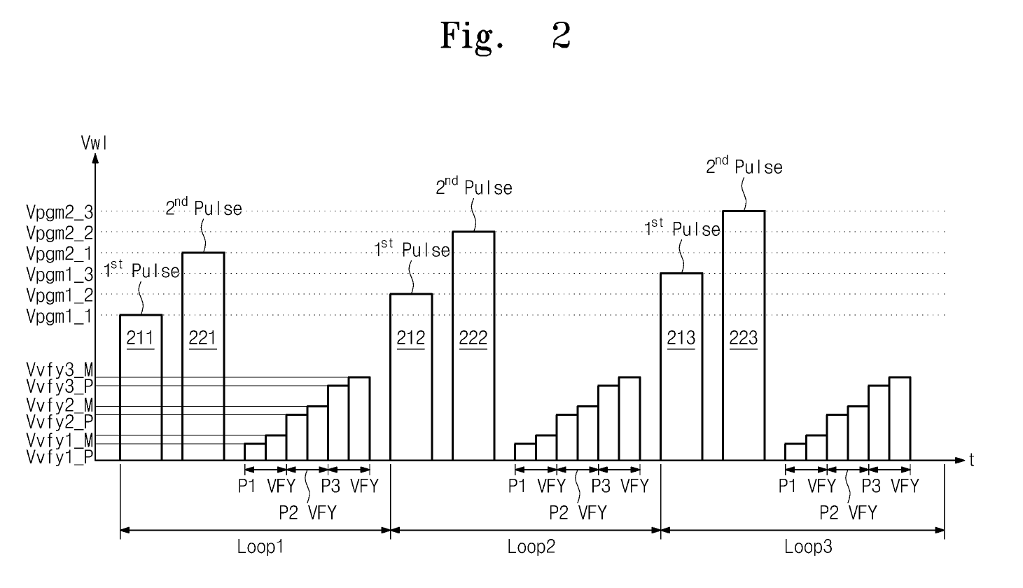

FIG. 2 is a waveform diagram illustrating voltages being supplied to a word line according to an example embodiment. Referring to FIG. 2, there is exemplarily illustrated the case that a dual pulse program operation and a 2-step verification operation are applied for the same period (e.g., program loop). In FIG. 2, a horizontal axis may indicate a time, and a vertical axis may indicate a level of a word line voltage Vwl.

A program cycle for programming all selected memory cells may include a plurality of program loops. Each program loop may include a program voltage period for a dual pulse program operation and a verification voltage period for a 2-step verification operation.

In a first loop, dual pulses may be applied to a selected word line. Dual pulse programming may be made to reduce a difference between program end times of all target states P1, P2, and P3. In contrast, if the same program voltage Vpgm is applied, programming of a memory cell to the target state P1 may be completed prior to programming of a memory cell to the target state P3. Accordingly, the ISPP operation using a relatively higher program start voltage may be applied to memory cells to be programmed to a target state of a high threshold voltage via the dual pulse programming.

For example, while a first pulse 211 is being applied to a selected word line, 0V may be supplied to bit lines of memory cells to be programmed to the target state P1. While the first pulse 211 is being applied to the selected word line, a program inhibition voltage Vdd may be supplied to bit lines of memory cells to be programmed to the target states P2 and P3. On the other hand, while a second pulse 221 is being applied to the selected word line, a program inhibition voltage Vdd may be supplied to bit lines of memory cells to be programmed to the target state P1. While the second pulse 221 is being applied to the selected word line, a forcing voltage (e.g., 1V) may be supplied to bit lines of memory cells to be programmed to the target state P2, and 0V may be supplied to bit lines of memory cells to be programmed to the target state P3.

After a program voltage formed of dual pulses 211 and 221 is applied, the target states P1, P2, and P3 may be verified. A verification operation P1 VFY for the target state P1 may be performed using a 2-step verification operation. For example, a pre-verification operation associated with memory cells to be programmed to the target state P1 may be executed using a first pre-verification voltage Vvfy1_P. At following program loops, bit line forcing voltage may be applied to memory cells determined to be passed as a result of the pre-verification operation using the first pre-verification voltage Vvfy1_P, for a period when the first pulse 212 or 213 is applied. Following the pre-verification operation, a main verification operation associated with memory cells to be programmed to the target state P1 may be executed using a first main verification voltage Vvfy1_M. In following program loops, memory cells determined to be passed as a result of the main verification operation using the first main verification voltage Vvfy1_M may be program inhibited.

A verification operation P2 VFY for the target state P2 may be performed using the 2-step verification operation. A pre-verification operation associated with memory cells to be programmed to the target state P2 may be executed using a second pre-verification voltage Vvfy2_P. In following program loops, memory cells determined to be passed as a result of the pre-verification operation using the second pre-verification voltage Vvfy2_P may be programmed by the first pulse. At a time when the first pulse is applied, 0V may be applied to bit lines of memory cells determined to be passed as a result of the pre-verification operation using the second pre-verification voltage Vvfy2_P. Following the pre-verification operation, a main verification operation associated with memory cells to be programmed to the target state P2 may be executed using a second main verification voltage Vvfy2_M. In following program loops, memory cells determined to be passed as a result of the main verification operation using the second main verification voltage Vvfy2_M may be program inhibited.

A verification operation P3 VFY for memory cells to be programmed to the target state P3 may be formed of a pre-verification operation using a third pre-verification voltage Vvfy3_P and a main verification operation using a third main-verification voltage Vvfy3_M.

Memory cells determined to be passed as a result of the pre-verification operation using the third pre-verification voltage Vvfy3_P may be programmed by a bit line forcing operation during following program loops. Following the pre-verification operation, a main verification operation associated with memory cells to be programmed to the target state P3 may be executed using the third main verification voltage Vvfy3_M. In following program loops, memory cells determined to be passed as a result of the main verification operation using the third main verification voltage Vvfy3_M may be program inhibited.

A program condition of a second loop may be identical to that of the first loop except that levels of dual pulses increase. There may be memory cells, each having a threshold voltage higher than the second main-verification voltage Vvfy2_M, from among memory cells to be programmed to the target state P2 for the first loop. Such memory cells may be programmed by the first pulse for the first loop. An operating condition of the second loop may be identical to that of the first loop except for two differences described above. Likewise, operating conditions of the remaining loops may be similar to that of the second loop.

With the above description, a dual pulse programming operation and a 2-step verification operation may be applied to memory cells to be programmed to the target state P2. It is possible to improve all program distributions by complexly applying a dual pulse programming operation and a 2-step verification operation to memory cells to be programmed to the target state P2.

FIG. 3 is a diagram illustrating a 2-step verification operation according to an example embodiment. Referring to FIG. 3, memory cells to be programmed to a target state TS may be verified by a 2-step verification operation.

A program voltage may be supplied to memory cells to be programmed to a target state TS. For example, selected memory cells may be programmed by the above-described dual pulse operation. Memory cells to be programmed to a target state TS via the 2-step verification operation using a pre-verification voltage Vvfy_P and a main verification voltage Vvfy_M may be divided into three or more groups according to a level of a threshold voltage.

Threshold voltages of the selected memory cells may be lower than the pre-verification voltage Vvfy_P. The memory cells may be supplied with a bit line voltage of 0V when a program voltage is applied to a word line. In following program loops, bit line forcing voltage may be applied to memory cells which have threshold voltages identical to or higher than the pre-verification voltage Vvfy_P and lower than the main verification voltage Vvfy_M. That is, a forcing voltage (e.g., 1V) may be applied to a bit line while a program pulse is applied to a selected word line. Memory cells, which have threshold voltages higher than the main verification voltage Vvfy_M, from among the selected memory cells may be program inhibited for following program loops.

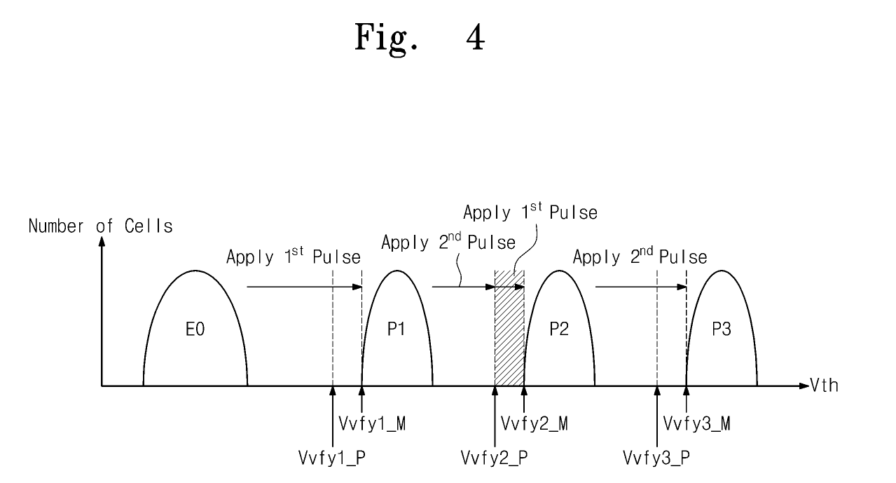

With the 2-step verification operation, memory cells each having a threshold voltage lower than the pre-verification voltage Vvfy_P may be programmed rapidly, and memory cells each having a threshold voltage higher than the pre-verification voltage Vvfy_P may be programmed slowly. Threshold voltages corresponding to a distribution 230 may be controlled to have threshold voltages corresponding to a distribution 240 according to the 2-step verification operation. The program procedure using the 2-step verification operation may be applied to memory cells to be programmed to target states P1 and P3. However, a 2-step verification operation may be applied in another manner to memory cells to be programmed to a target state to which bit line forcing voltage is applied initially. This will be more fully described with reference to FIG. 4.

FIG. 4 is a diagram for describing a dual pulse program manner and a 2-step verification manner according to an example embodiment. An example embodiment will be described using a program procedure of a 2-bit multi-level cell (MLC).

Memory cells to be programmed to a target state P1 may be programmed by a first pulse, which is applied firstly, from among two pulses for each program loop. During a period where the first pulse is applied to a selected word line, a page buffer 130 (refer to FIG. 1) may provide one of 0V, a bit line forcing voltage (e.g., 1V), and an inhibition voltage Vdd to bit lines of memory cells to be programmed to the target state P1.

Memory cells, which have threshold voltages lower than a first pre-verification voltage Vvfy1_P, from among the memory cells to be programmed to the target state P1 may be supplied with 0V via corresponding bit lines when the first pulse is applied at a following program loop. Memory cells, which have threshold voltages higher than the first pre-verification voltage Vvfy1_P and lower than a first main verification voltage Vvfy1_M, may be supplied with the forcing voltage (e.g., 1V) via corresponding bit lines when the first pulse is applied for a following program loop. Memory cells, which have threshold voltages higher than the first main verification voltage Vvfy1_M, may be supplied with the inhibition voltage Vdd via corresponding bit lines when the first pulse is applied for a following program loop. Accordingly, memory cells to be programmed to the target state P1 may be programmed only by the first pulse.

As a program voltage, a first pulse and a second pulse may be applied to a selected word line of memory cells to be programmed to a target state P2. During a first program loop, an inhibition voltage may be supplied to a bit line when the first pulse is applied. When the second pulse is applied, the bit line forcing voltage (e.g., 1V) may be supplied to a bit line. Memory cells each having a threshold voltage lower than a second pre-verification voltage Vvfy2_P may be programmed by the above-described operation. That is, memory cells may be programmed to have a threshold voltage higher than the second pre-verification voltage Vvfy2_P by the second pulse and the bit line forcing voltage.

Memory cells, which have threshold voltages higher than the second pre-verification voltage Vvfy2_P and lower than the second main verification voltage Vvfy2_M, from among the memory cells to be programmed to the target state P2 may be supplied with 0V via corresponding bit lines when the first pulse is applied for a following program loop. Memory cells, which have threshold voltages higher than the second main verification voltage Vvfy2_M, may be supplied with the inhibition voltage Vdd via corresponding bit lines for a next following program loop.

For example, memory cells to be programmed to a target state P3 may be programmed by a second pulse of the dual pulse. That is, the memory cells to be programmed to the target state P3 may be supplied with an inhibition voltage Vdd via corresponding bit lines when the first pulse is applied for all program loops. Memory cells, which have threshold voltages lower than a third pre-verification voltage Vvfy3_P, may be supplied with 0V via corresponding bit lines when the second pulse is applied. Memory cells, which have threshold voltages higher than the third pre-verification voltage Vvfy3_P and lower than a third main verification voltage Vvfy3_M, may be supplied with the bit line forcing voltage (e.g., 1V) via corresponding bit lines when the second pulse is applied for a following program loop. Memory cells, which have threshold voltages higher than the third main verification voltage Vvfy3_M, may be supplied with the inhibition voltage Vdd via corresponding bit lines.

With the above description, any one of a dual pulse may be supplied to a word line of memory cells to be programmed to the target states P1 and P3. On the other hand, memory cells to be programmed to the target state P2 may be programmed by a second pulse of the dual pulse and bit line forcing voltage initially. However, memory cells, which have threshold voltages higher than a reference voltage (e.g., Vvfy2_P), from among memory cells to be programmed to the target state P2 may be programmed by the first pulse during a second through nth program loops after a first program loop, the n is a natural number and is greater than 2. A level of a second pulse of a previous loop may be higher than a first pulse of a current loop. Accordingly, a program speed of memory cells to be programmed to the target state P2 may be improved upon programming using the first pulse. 0V may be applied to a bit line during a time when the first pulse is applied to a word line during a second through nth program loops.

With the above description, it is possible to combine a dual pulse program and a 2-step verification operation in relation to memory cells to be programmed to the target state P2.

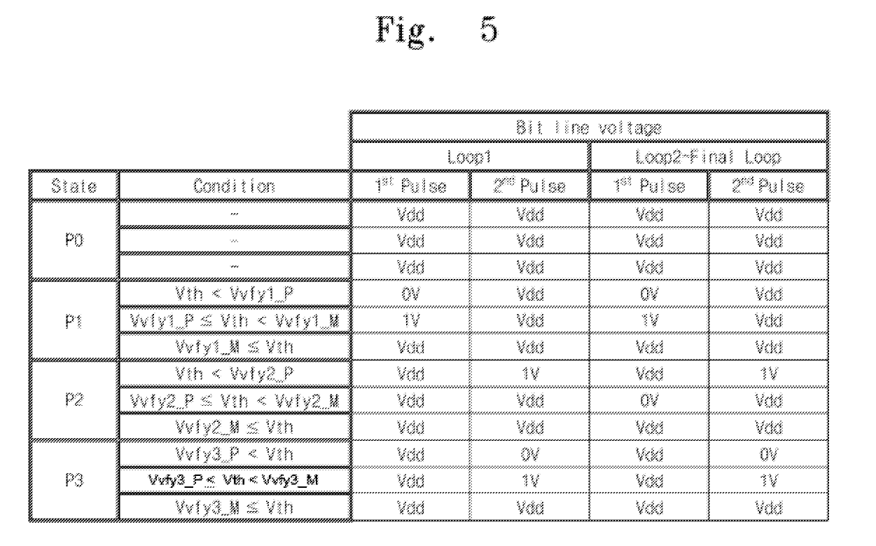

FIG. 5 is a diagram illustrating a voltage condition of a dual pulse program and 2-step verification operation according to an example embodiment. In FIG. 5, there is illustrated a bit line voltage associated with a threshold voltage of a memory cell to be programmed to each of target states P1, P2, and P3.

A bit line voltage applied at a program operation may be divided on the basis of a first loop and a second to a final loop. This may be to define the case that from among memory cells to be programmed to the target state P2, threshold voltages increase to be higher than a second pre-verification voltage Vvfy2_P according to an execution result of a first loop. A bias condition of bit lines of memory cells to be programmed to the target states P1 and P3 may be identically applied to all loops.

During all program operation periods, an inhibition voltage Vdd may be applied to bit lines of memory cells to be programmed a target state of which are an erase state E0.

In one embodiment, Memory cells to be programmed to the target state P1 may be programmed by a first pulse of a dual pulse for all program loops. During a pulse period where the first pulse is applied to a word line for a number of program loops, a voltage of 0V may be supplied to bit lines of memory cells until each of the memory cells reaches a threshold voltage higher than a first pre-verification voltage Vvfy1_P. During at least second program loop where a first pulse is applied to a word line, a forcing voltage (e.g., 1V) may be supplied to bit lines of memory cells if each of memory cells has a threshold voltage higher than the first pre-verification voltage Vvfy1_P and lower than a first main verification voltage Vvfy1_M. An inhibition voltage Vdd may be supplied to bit lines of memory cells each having a threshold voltage higher than the first main verification voltage Vvfy1_M. In one embodiment, there are no memory cells having a threshold voltage higher than the first main verification voltage Vvfy1_M during a period of a first program loop.

In one embodiment, as a program voltage, a first pulse and a second pulse may be applied to memory cells to be programmed to a target state P2. During a number of program loops, an inhibition voltage may be supplied to bit lines of memory cells when the first pulse is applied. When the second pulse is applied, the forcing voltage (e.g., 1V) may be supplied to bit lines of memory cells until each of the memory cells reaches a threshold voltage higher than a second pre-verification voltage Vvfy2_P. When the first pulse is applied to a word line, the inhibition voltage Vdd may be supplied to bit lines of memory cells each having a threshold voltage higher than the second pre-verification voltage Vvfy2_P and lower than a second main verification voltage Vvfy2_M. Memory cells, which have threshold voltages higher than the second main verification voltage Vvfy2_M, may be supplied with the inhibition voltage Vdd via corresponding bit lines during a following program loop. In one embodiment, a verifying operation may precede a first program loop for programming to the target state P2.

Memory cells to be programmed to a target state P3 may be programmed by a second pulse of the dual pulse. For example, the memory cells to be programmed to the target state P3 may be supplied with an inhibition voltage Vdd via corresponding bit lines when the first pulse is applied for a number of program loops. Memory cells may be supplied with 0V via corresponding bit lines when the second pulse is applied until each of the memory cells reaches a threshold voltage higher than a third pre-verification voltage Vvfy3_P. Memory cells, which have threshold voltages higher than the third pre-verification voltage Vvfy3_P and lower than a third main verification voltage Vvfy3_M, may be supplied with the forcing voltage (e.g., 1V) via corresponding bit lines when the second pulse is applied during at least second program loop. Memory cells, which have threshold voltages higher than the third main verification voltage Vvfy3_M, may be supplied with the inhibition voltage Vdd via corresponding bit lines. In one embodiment, there are no memory cells having a threshold voltage higher than the third main verification voltage Vvfy3_M during a period of a first program loop

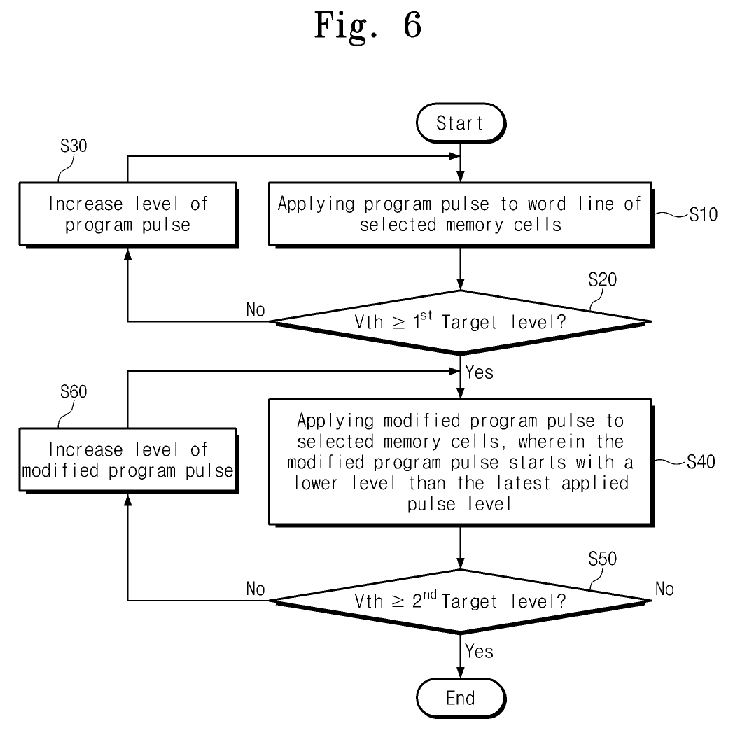

FIG. 6 is a flowchart for describing a program method according to an example embodiment. Referring to FIG. 6, programming of memory cells to be programmed to a specific program state may start by a bit line forcing operation. If threshold voltages of memory cells become higher than a first target level, a program pulse having a level lower than that of a previously applied program pulse may be supplied to a word line. Detailed description will be disclosed below.

In operation S10, a program pulse may be supplied to a word line of memory cells to be programmed to a specific target state. The program pulse can be formed of one-pulse, dual pulse, or three or more pulse.

In operation S20, a verification operation may be carried out to detect whether threshold voltages of the selected memory cells become higher than the first target level. If threshold voltages of the selected memory cells are lower than the first target level, the method proceeds to operation S30. If threshold voltages of the selected memory cells are higher than the first target level, the method proceeds to operation S40.

In operation S30, a level of the program pulse may be increased to program memory cells each having a threshold voltage lower than the first target level. Then, the method proceeds to operation S10, in which memory cells each having a threshold voltage lower than the first target level are programmed by the program pulse having the increased level.

In operation S40, memory cells, which have threshold voltages higher than the first target level, from among the selected memory cells may be programmed by a program pulse having a level lower than that of a finally provided program pulse. That is, a word line may be supplied with a modified program pulse which is set to be lower in level than a program pulse provided at a previous program loop.

In operation S50, a verification operation may be carried out to detect whether threshold voltages of the selected memory cells become higher than a second target level. If a threshold voltage of at least one of the selected memory cells is lower than the second target level, the method proceeds to operation S60. If threshold voltages of the selected memory cells all are higher than the second target level, the method may be ended.

In operation S60, a level of the program pulse may be increased. A program operation using the program pulse having the increased level may be performed in operation S40. If a memory cell having a threshold voltage lower in level than the second target level from among the selected memory cells exists, the operations S40, S50, and S60 may be iterated.

If a threshold voltage of a memory cell to be programmed to a specific state is higher than a reference, a word line may be supplied with a program pulse having a level lower than that of a previously applied program pulse. Accordingly, a program speed may become slow, so that a distribution is easily controlled.

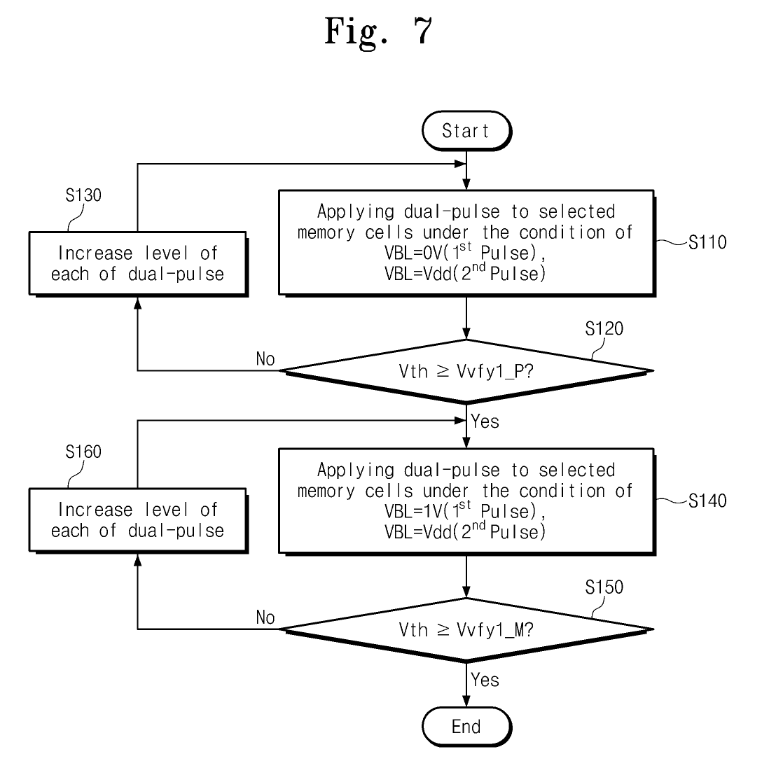

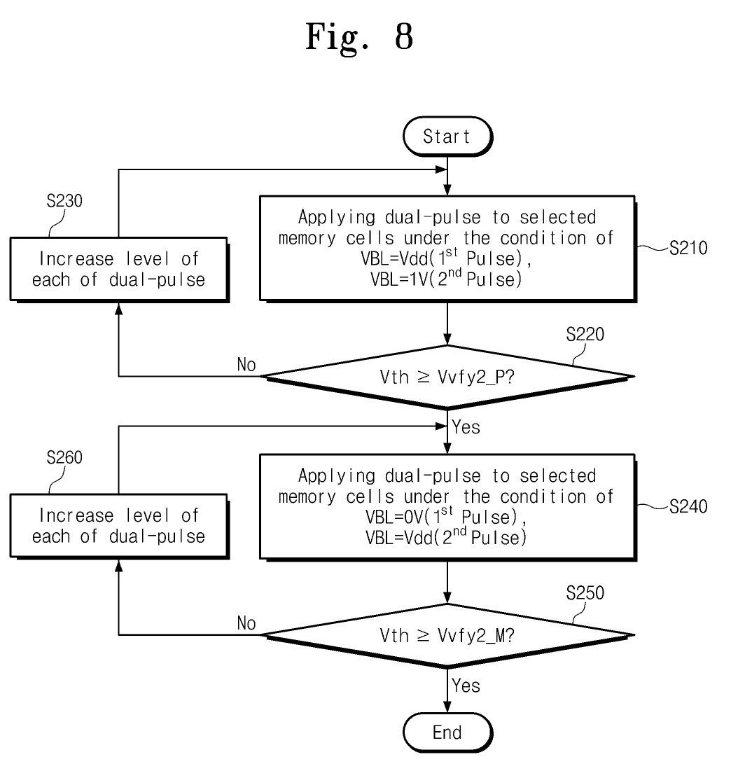

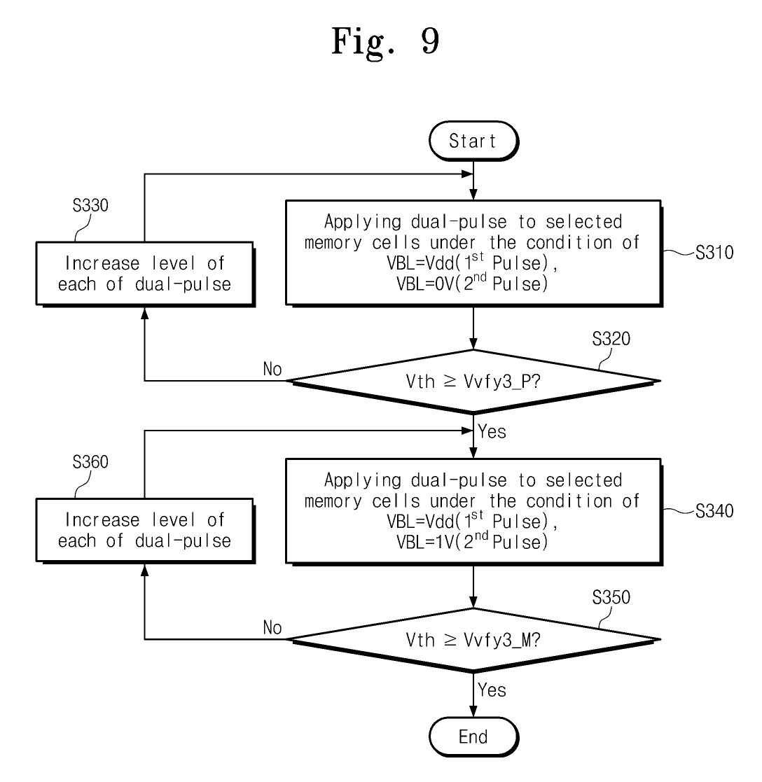

FIGS. 7 through 9 are flowcharts for describing program method of target states according to some example embodiments. FIG. 7 is a flowchart for describing a program method of memory cells to be programmed to a target state P1. FIG. 8 is a flowchart for describing a program method of memory cells to be programmed to a target state P2. FIG. 9 is a flowchart for describing a program method of memory cells to be programmed to a target state P3.

Referring to FIG. 7, memory cells to be programmed to a target state P1 may be programmed using a first pulse of a dual pulse.

In operation S110, a dual pulse may be applied to a word line of selected memory cells. For a first pulse period, 0V may be supplied to bit lines of memory cells to be programmed to the target state P1. For a second pulse period, an inhibition voltage Vdd may be supplied to the bit lines of the memory cells to be programmed to the target state P1.

In operation S120, a verification operation may be carried out to detect whether threshold voltages of the selected memory cells become higher than a first pre-verification voltage Vvfy1_P. If threshold voltages of the selected memory cells are lower than the first pre-verification voltage Vvfy1_P, the step proceeds to operation S130. If threshold voltages of the selected memory cells are higher than the first pre-verification voltage Vvfy1_P and are lower than a first main verification voltage Vvfy1_M, the operation proceeds to operation S140.

In operation S130, a level of the program pulse may be increased to program memory cells each having a threshold voltage lower than the first pre-verification voltage Vvfy1_P from among the selected memory cells. Then, the operation proceeds to operation S110, in which memory cells each having a threshold voltage lower than the first pre-verification voltage Vvfy1_P are programmed by the program pulse having the increased level.

In operation S140, memory cells, which have threshold voltages higher than the first pre-verification voltage Vvfy1_P and lower than the first main verification voltage Vvfy1_M, from among the selected memory cells may be programmed by a bit line forcing operation where a program speed is relatively slow. For example, a word line of the selected word line may be supplied with a dual pulse having a higher level as compared with a previous program loop. During a first pulse period, a forcing voltage (e.g., 1V) may be supplied to bit lines of memory cells to be programmed to the target state P1. During a second pulse period, an inhibition voltage Vdd may be supplied to bit lines of memory cells to be programmed to the target state P1.

In operation S150, a verification operation may be carried out to detect whether threshold voltages of the selected memory cells become higher than the first main verification voltage Vvfy1_M. If threshold voltages of the selected memory cells are lower than the first main verification voltage Vvfy1_M, the operation proceeds to operation S160. If threshold voltages of the selected memory cells are higher than the first main verification voltage Vvfy1_M, the operation may be ended.

In operation S160, a level of each of first and second pulses of the dual pulse may be increased. A program operation using the pulses each having an increased level may be performed in operation S140. In particular, during a period where the first pulse having the increased level is applied, a program operation may be executed under the condition that the forcing voltage (e.g., 1V) is supplied to a bit line. If a memory cell having a threshold voltage lower in level than the first main verification voltage Vvfy1_M from among the selected memory cells exists, the operations S140, S150, and S160 may be iterated.

Referring to FIG. 8, memory cells to be programmed to a target state P2 may be programmed using a first pulse and a second pulse forming a dual pulse.

In operation S210, a dual pulse may be applied to a word line of selected memory cells. During a first pulse period, an inhibition voltage (e.g., Vdd) may be supplied to bit lines of memory cells to be programmed to the target state P2. During a second pulse period, a forcing voltage (e.g., 1V) may be supplied to the bit lines of the memory cells to be programmed to the target state P2. Accordingly, memory cells to be programmed to a target state P2 may be programmed using the second pulse and a bit line forcing voltage.

In operation S220, a verification operation may be carried out to detect whether threshold voltages of the selected memory cells become higher than a second pre-verification voltage Vvfy2_P. If a threshold voltage of at least one of the selected memory cells is lower than the second pre-verification voltage Vvfy2_P, the operation proceeds to operation S230. If threshold voltages of the selected memory cells all are higher than the second pre-verification voltage Vvfy2_P and are lower than a second main verification voltage Vvfy2_M, the operation proceeds to operation S240.

In operation S230, a level of the program pulse may be increased to program memory cells each having a threshold voltage lower than the second pre-verification voltage Vvfy2_P from among the selected memory cells. Then, the operation proceeds to operation S210, in which memory cells each having a threshold voltage lower than the second pre-verification voltage Vvfy2_P are programmed by the program pulse having the increased level.

In operation S240, memory cells, which have threshold voltages higher than the second pre-verification voltage Vvfy2_P and lower than the second main verification voltage Vvfy2_M, from among the selected memory cells may be programmed by a program pulse having a level lower than that of a finally provided program pulse. For example, memory cells having threshold voltages lower than the second pre-verification voltage Vvfy2_P may be programmed using the second pulse. During a second pulse period, a forcing voltage (e.g., 1V) may be supplied to bit lines. However, memory cells having threshold voltages higher than the second pre-verification voltage Vvfy2_P may be programmed using the first pulse. At this time, a bit line voltage may be set to 0V. During a second pulse period, an inhibition voltage Vdd may be supplied to bit lines.

Widening of a threshold voltage distribution may be prevented by programming memory cells using a second pulse and then programming a first pulse when threshold voltages of the memory cells being programmed using the second pulse become higher than the second pre-verification voltage Vvfy2_P and lower than the second main verification voltage Vvfy2_M. This may be because the first pulse is lower in level than the second pulse. A program speed may become slow by changing a program voltage from the second pulse to the first pulse.

In operation S250, a verification operation may be carried out to detect whether threshold voltages of the selected memory cells become higher than a second main verification voltage Vvfy2_M. If a threshold voltage of at least one of the selected memory cells is lower than the second main verification voltage Vvfy2_M, the operation proceeds to operation S260. If threshold voltages of the selected memory cells are higher than the second main verification voltage Vvfy2_M, the operation may be ended.

In operation S260, a level of each of first and second pulses of the dual pulse may be increased. A program operation using the pulses each having an increased level may be performed in operation S240. In particular, for a period where the first pulse having the increased level is applied, a program operation may be executed under the condition that 0V is supplied to a bit line. If a memory cell having a threshold voltage lower in level than the second main verification voltage Vvfy2_M from among the selected memory cells to be programmed to the target state P2 exists, the operations S240, S250, and S260 may be iterated.

With the above description, first, memory cells may be programmed using a forcing voltage and a pulse having a relatively high level of a dual pulse. Then, if a threshold voltage of a memory cell becomes higher than a specific level (e.g., Vvfy2_P), memory cells may be programmed using a pulse having a relatively low level of the dual pulse. After pulse switching, 0V may be supplied to bit lines of selected memory cells. It is possible to program memory cells to be programmed to a program state P2 using a 2-step verification operation. Accordingly, a difference between distributions of program states may be reduced, and a burden of designing a read margin and an ECC may be reduced.

Referring to FIG. 9, memory cells to be programmed to a target state P3 may be programmed using a second pulse of a dual pulse.

In operation S310, a dual pulse may be applied to a word line of selected memory cells. During a first pulse period, an inhibition voltage (e.g., Vdd) may be supplied to bit lines of memory cells to be programmed to the target state P3. During a second pulse period, 0V may be supplied to the bit lines of the memory cells to be programmed to the target state P3.

In operation S320, a verification operation may be carried out to detect whether threshold voltages of the selected memory cells become higher than a third pre-verification voltage Vvfy3_P. If a threshold voltage of at least one of the selected memory cells is lower than the third pre-verification voltage Vvfy3_P, the operation proceeds to operation S330. If threshold voltages of the selected memory cells all are higher than the third pre-verification voltage Vvfy3_P, the operation proceeds to operation S340.

In operation S330, a level of the program pulse may be increased to program memory cells each having a threshold voltage lower than the third pre-verification voltage Vvfy3_P from among the selected memory cells. Then, the operation proceeds to operation S310, in which memory cells each having a threshold voltage lower than the third pre-verification voltage Vvfy3_P are programmed by the program pulse having the increased level.

In operation S340, memory cells, which have threshold voltages higher than the third pre-verification voltage Vvfy3_P, from among the selected memory cells may be programmed by a bit line forcing operation where a program speed is relatively slow. For example, a word line of the selected word line may be supplied with a dual pulse having a higher level as compared with a previous program loop. During a second pulse period, a forcing voltage (e.g., 1V) may be supplied to bit lines of memory cells to be programmed to the target state P3. During a first pulse period, an inhibition voltage Vdd may be supplied to bit lines of memory cells to be programmed to the target state P3.

In operation S350, a verification operation may be carried out to detect whether threshold voltages of the selected memory cells become higher than a third main verification voltage Vvfy3_M. If a threshold voltage of at least one of the selected memory cells is lower than the third main verification voltage Vvfy3_M, the operation proceeds to operation S360. If threshold voltages of the selected memory cells all are higher than the third main verification voltage Vvfy3_M, the operation may be ended.

In operation S360, a level of each of first and second pulses of the dual pulse may be increased. A program operation using the pulses each having an increased level may be performed in operation S340. In particular, at a period where the second pulse having the increased level is applied, a program operation may be executed under the condition that 0V is supplied to a bit line. If a memory cell having a threshold voltage lower in level than the third main verification voltage Vvfy3_M from among the selected memory cells exists, the operations S340, S350, and S360 may be iterated.

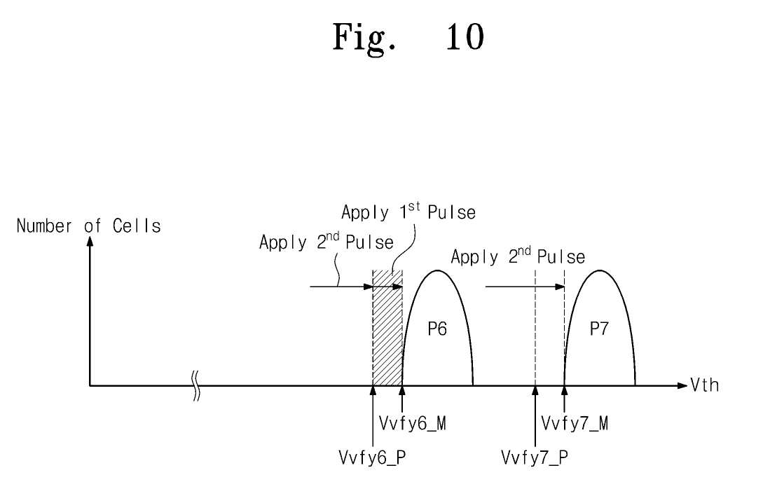

FIG. 10 is a diagram illustrating another embodiment of the inventive concept. In FIG. 10, there is illustrated a program method of a 3-bit multi-level cell (MLC) according to an embodiment of the inventive concept.

The present disclosure may be applied to multi-level cells storing three or more bits of data. Memory cells to be programmed to a specific target state (e.g., P6) may be programmed using a second pulse of a dual pulse and a forcing voltage at an initial program step. For example, during a first program loop, when a first pulse is applied to a word line, an inhibition voltage Vdd may be supplied to a bit line. When a second pulse is applied to a word line, a forcing voltage (e.g., 1V) may be supplied to a bit line. Memory cells each having a threshold voltage lower than a sixth pre-verification voltage Vvfy6_P may be programmed by the above-described operation. That is, memory cells may be programmed to have a threshold voltage higher than the sixth pre-verification voltage Vvfy6_P using a forcing voltage and a second pulse.

From among memory cells to be programmed to the target state P6, memory cells may be selected which have threshold voltages higher than the sixth pre-verification voltage Vvfy6_P and lower than a sixth main verification voltage Vvfy6_M. During following program loops, the selected memory cells may be supplied with 0V via corresponding bit lines when a first pulse is supplied to a word line. During following program loops, an inhibit voltage Vdd may be supplied via corresponding bit lines to memory cells each having a threshold voltage higher than the sixth main verification voltage Vvfy6_M.

Memory cells to be programmed to a target state P7 may be programmed using a second pulse of a dual pulse. That is, during all program loops, when a first pulse is applied to a word line, an inhibition voltage Vdd may be supplied via bit lines to memory cells to be programmed to the target state P7. Memory cells each having a threshold voltage lower than a seventh pre-verification voltage Vvfy7_P may be supplied with 0V via corresponding bit lines when the second pulse is applied to a word line. Memory cells may be selected which have threshold voltages higher than the seventh pre-verification voltage Vvfy7_P and lower than a seventh main verification voltage Vvfy7_M. After a following program loop, the selected memory cells may be supplied with a forcing voltage (e.g., 1V) via corresponding bit lines when the second pulse is applied to a word line. An inhibition voltage Vdd may be supplied to bit lines of memory cells each having a threshold voltage higher than the seventh main verification voltage Vvfy7_M.

With the above description, one pulse of a dual pulse may be selectively provided to a word line of memory cells to be programmed to a target state P7. Memory cells to be programmed to a target state P6 may be programmed using a second pulse and a forcing voltage. And then, from among the memory cells to be programmed to the target state P6, memory cells each having a threshold voltage higher than a reference level (e.g., Vvfy6_P) may be programmed using a first pulse. While the first pulse is being applied to a word line, 0V may be supplied to a bit line.

With the above-described operation, it is possible to apply a dual pulse programming and 2-step verification scheme to memory cells to be programmed to the target state P6. However, the present disclosure is not limited thereto. For example, the disclosure can be applied to a program manner where three or more pulses are used as a program voltage. Further, the embodiments can be applied to memory cells which store four or more bits of data as well as two or three bits of data.

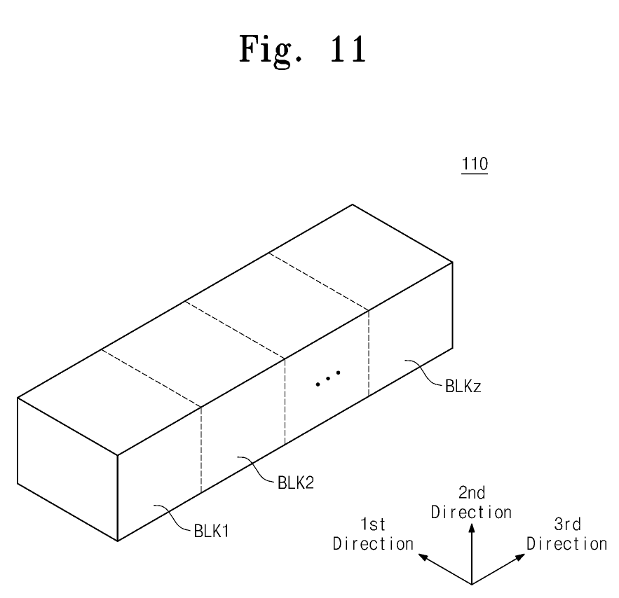

FIG. 11 is a diagram illustrating a memory cell array in FIG. 1 according to an example embodiment. Referring to FIG. 11, a memory cell array 110 may include a plurality of memory blocks BLK1 to BLKz, each of which is formed to have a three-dimensional structure (or, a vertical structure). For example, each of the memory blocks BLK1 to BLKz may include structures extending along first to third directions x, y, and z. Each of the memory blocks BLK1 to BLKz may include a plurality of NAND cell strings extending along the third direction z.

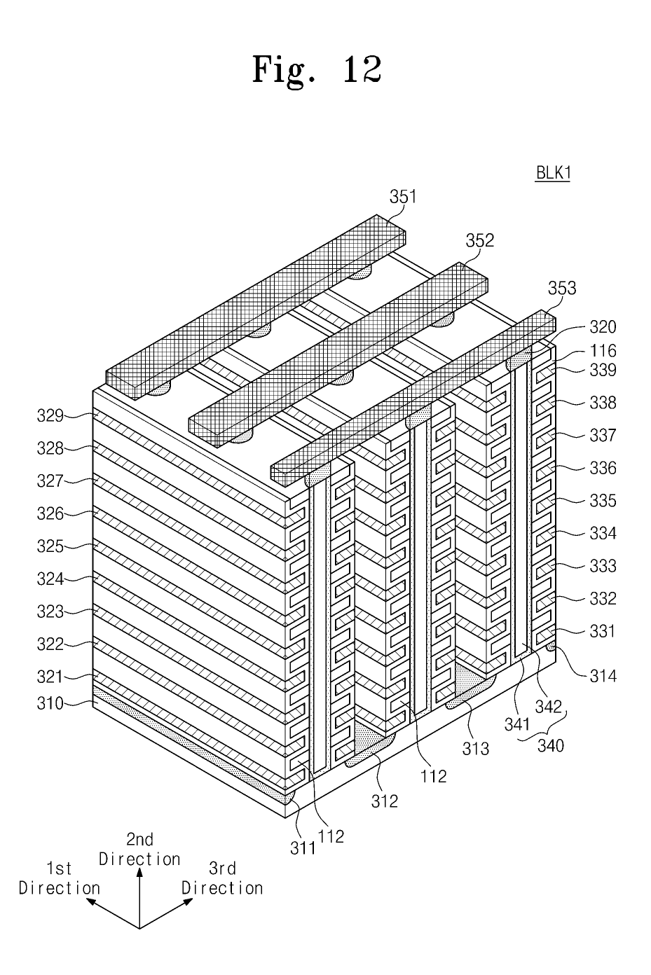

Each NAND cell string may be coupled with a bit line BL, a string selection line SSL, a plurality of word lines WL, a ground selection line GSL, and a common source line CSL. That is, each memory block may be connected with a plurality of bit lines BL, a plurality of string selection lines SSL, a plurality of ground selection lines GSL, a plurality of word lines WL, and a common source line CSL. The memory blocks BLK1 to BLKz will be more fully described with reference to FIG. 12.

FIG. 12 is a perspective view illustrating one of memory blocks in FIG. 11 according to an example embodiment. Referring to FIG. 12, a memory block BLK1 may include structures extending along first to third directions x, y, and z.

A substrate 310 may be provided to form the memory block BLK1. The substrate 310 may be formed of a p-well in which Group V such as boron is injected. Alternatively, the substrate 310 may be a pocket p-well provided within an n-well. Below, it is assumed that the substrate 310 is a p-well. However, the substrate 310 is not limited to a p-well.

A plurality of doping regions 311 to 314 extending along the first direction x may be provided in the substrate 310. The first to fourth doping regions 311 to 314 may have an n-type conductive material different from that of the substrate 310. Below, it is assumed that the first to fourth doping regions 311 to 314 are n-types. However, the first to fourth doping regions 311 to 314 are not limited to the n-type.

On the substrate 310 between the first and second doping regions 311 and 312, a plurality of pillars 340 may be arranged sequentially along the second direction so as to penetrate a plurality of insulation materials along the third direction. For example, the pillars 340 may contact with the substrate 310 through the insulation materials. Herein, the pillar 340 may be formed on the substrate 310 between the second and third doping regions 312 and 313 as well as on the substrate 310 between third and fourth doping regions 313 and 314.

The pillars 340 may be formed of a plurality of materials, respectively. For example, a surface layer 341 of each pillar 340 may include a silicon material doped by a first type. For example, the surface layer 341 of each pillar 340 may include a silicon material doped by the same type as the substrate 310. Below, it is assumed that the surface layer 341 of each pillar 340 includes p-type silicon. However, the surface layer 341 of each pillar 340 is not limited to the p-type silicon.

An inner layer 342 of each pillar 340 may be formed of an insulation material. For example, the inner layer 342 of each pillar 340 may include an insulation material such as silicon oxide. For example, the inner layer 342 of each pillar 340 may include air gap.

Between the first and second doping regions 311 and 312, first conductive materials 321 to 329 may be provided on an exposed surface of the insulation film 116. For example, the first conductive material 321 extending along the second direction y may be provided between the substrate 310 and an insulation material adjacent to the substrate 310. In particular, the first conductive material 321 extending along the first direction x may be provided between the substrate 310 and the insulation film 116 of a lower surface of the insulation material 112 adjacent to the substrate 310.

The first conductive material extending along the first direction may be provided between the insulation film 116 of an upper surface of a specific insulation material of the insulation materials 112 and the insulation film 116 of a lower surface of an insulation material disposed at an upper portion of the specific insulation material. In an embodiment, a plurality of conductive materials 321 to 329 extending along the first direction may be provided between the insulation materials 112. The conductive materials 321 to 329 extending may be a metallic material. The conductive materials 321 to 329 may be a conductive material such as polysilicon.

The same structure as that on the first and second doping regions 311 and 312 may be provided at an area between the second and third doping regions 312 and 313. For example, at an area between the second and third doping regions 312 and 313, there may be provided a plurality of insulation materials 112 extending in the first direction, a plurality of pillars 340 disposed sequentially along the first direction so as to penetrate the insulation materials 112 along the third direction, an insulation film 116 provided on exposed surfaces of the plurality of pillars 340, and a plurality of conductive materials 321 to 329 extending along the first direction.

The same structure as that on the first and second doping regions 311 and 312 may be provided at an area between the third and fourth doping regions 313 and 314. For example, at an area between the third and fourth doping regions 313 and 314, there may be provided a plurality of insulation materials 112 extending in the first direction, a plurality of pillars 340 disposed sequentially along the first direction so as to penetrate the insulation materials 112 along the third direction, an insulation film 116 provided on exposed surfaces of the plurality of pillars 340, and a plurality of conductive materials 321 to 329 extending along the first direction.

Drains 321 may be provided on the pillars 340, respectively. The drains 320 may be second-type silicon materials. The drains 321 may be n-type silicon materials. Below, it is assumed that the drains 321 include n-type silicon materials. However, the drains 321 are not limited to include n-type silicon materials. A width of each drain 321 may be wider than that of a corresponding pillar 340. Each drain 321 may be provided on an upper surface of a corresponding pillar 340 in a pad structure.

Second conductive materials 351 to 353 extending along the third direction may be provided on the drains 321. The second conductive materials 351 to 353 may be disposed sequentially along the first direction. The second conductive materials 351 to 353 may be connected with corresponding drains 321, respectively. For example, the drains 321 and the second conductive material 353 extending along the third direction may be connected via contact plugs, respectively. The second conductive materials 351 to 353 may be a metallic material. The second conductive materials 351 to 353 may be a conductive material such as polysilicon.

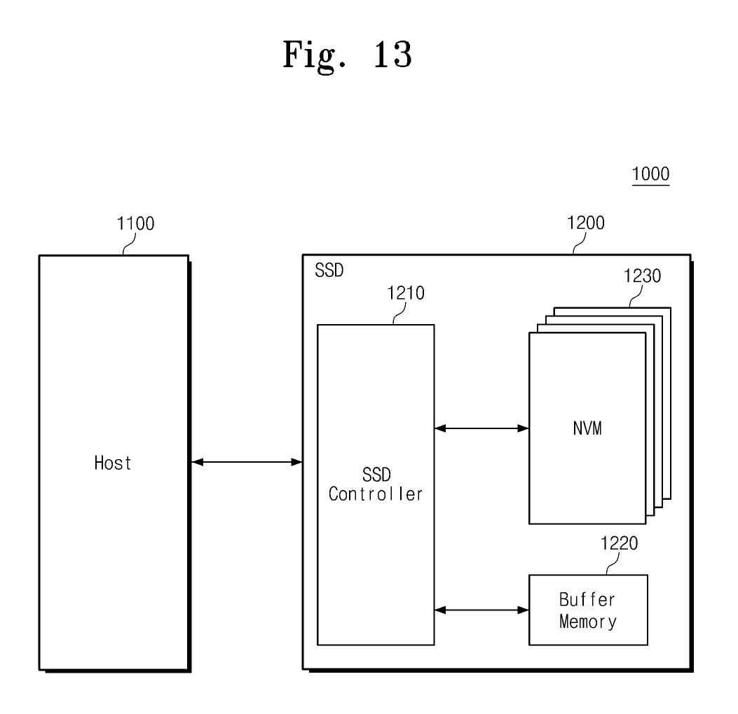

FIG. 13 is a block diagram illustrating a user device including a solid state disk according to an example embodiment. Referring to FIG. 13, a user device 1000 may include a host 1100 and an SSD 1200. The SSD 1200 may include an SSD controller 1210, a buffer memory 1220, and a nonvolatile memory device 1230.

The SSD controller 1210 may provide physical interconnection between the host 1100 and the SSD 1200. The SSD controller 1210 may provide an interface with the SSD 1200 corresponding to a bus format of the host 1100. In particular, the SSD controller 1210 may decode a command provided from the host 1100. The SSD controller 1210 may access the nonvolatile memory device 1230 according to the decoding result. The bus format of the host 1100 may include USB (Universal Serial Bus), SCSI (Small Computer System Interface), PCI express, ATA, PATA (Parallel ATA), SATA (Serial ATA), SAS (Serial Attached SCSI), and the like.

The buffer memory 1220 may temporarily store write data provided from the host 1100 or data read out from the nonvolatile memory device 1230. In the event that data existing in the nonvolatile memory device 1230 is cached at a read request of the host 1100, the buffer memory 1220 may support a cache function of providing cached data directly to the host 1100. Typically, a data transfer speed of a bus format (e.g., SATA or SAS) of the host 1100 may be higher than that of a memory channel of the SSD 1200. That is, in the event that an interface speed of the host 1100 is remarkably fast, lowering of the performance due to a speed difference may be minimized by providing the buffer memory 1220 having a large storage capacity.

The buffer memory 1220 may be formed of a synchronous DRAM to provide sufficient buffering to the SSD 1200 used as an auxiliary mass storage device. However, the buffer memory 1220 is not limited to this disclosure.

The nonvolatile memory device 1230 may be provided as a storage medium of the SSD 1200. For example, the nonvolatile memory device 1230 may be formed of a NAND flash memory device having a mass storage capacity. The nonvolatile memory device 1230 may be formed of a plurality of memory devices. In this case, memory devices may be connected with the SSD controller 1210 by a channel unit. The nonvolatile memory device 1230 is not limited to a NAND flash memory device. For example, a PRAM, an MRAM, a ReRAM, a FRAM, a NOR flash memory, etc. may be used as a storage medium of the SSD 1200. Further, the inventive concept may be applied to a memory system which uses different types of memory devices together. The nonvolatile memory device 1230 may be configured substantially the same as that described FIG. 1.

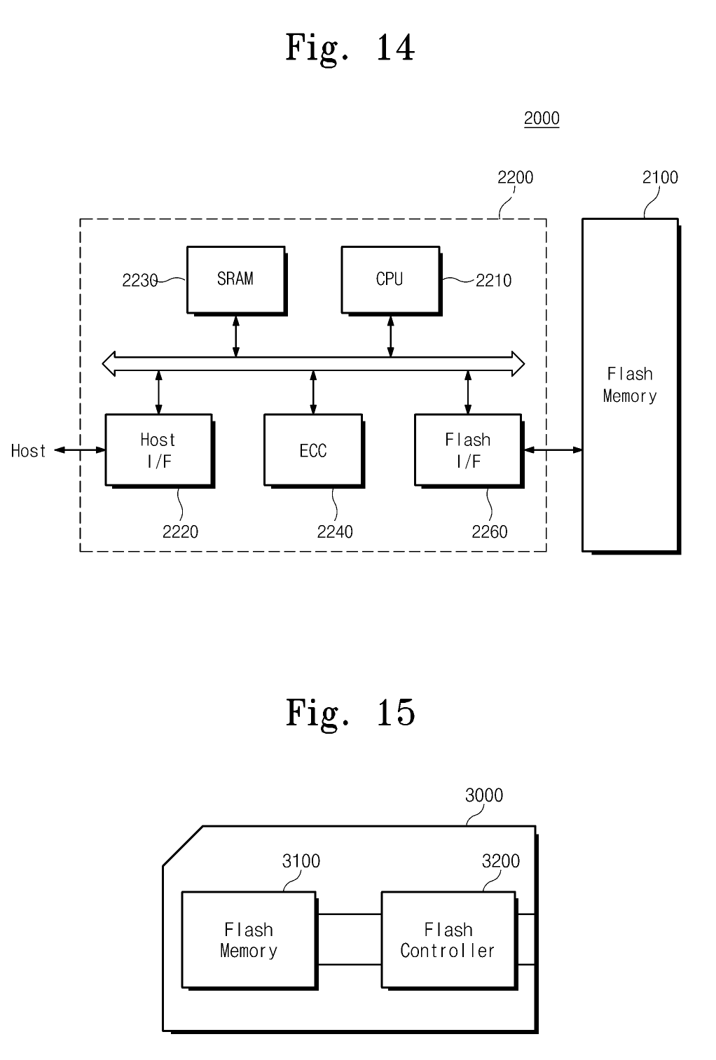

FIG. 14 is a block diagram illustrating a memory system according to another embodiment. Referring to FIG. 14, a data storage device 2000 may include a memory controller 2200 and a flash memory 2100.

The flash memory 2100 may be the same as that illustrated in FIG. 1, and description thereof is thus omitted.

The memory controller 2200 may be configured to control the flash memory 2100. An SRAM 2230 may be used as a working memory. A host interface 2220 may include the data exchange protocol of a host connected with the data storage device 2000. An ECC circuit 2240 may be configured to detect and correct an error of data read out from the flash memory 2100. A memory interface 2260 may be configured to interface with the flash memory 2100 according to an embodiment of the inventive concept. A CPU 2210 may be configured to perform an overall control operation for exchanging data. Although not shown, the data storage device 2000 may further include a ROM which stores code data for interfacing with a host.

The memory controller 2100 may be configured to communicate with an external device (e.g., a host) via one of various interface protocols such as USB, MMC, PCI-E, SAS, SATA, PATA, SCSI, ESDI, IDE, etc.

The memory system 2000 according to the present disclosure may be applied to one of various user devices such as computer, portable computer, Ultra Mobile PC (UMPC), workstation, net-book, PDA, web tablet, wireless phone, mobile phone, smart phone, e-book, PMP (portable multimedia player), digital camera, digital audio recorder/player, digital picture/video recorder/player, portable game machine, navigation system, black box, 3-dimensional television, a device capable of transmitting and receiving information at a wireless circumstance, one of various electronic devices constituting home network, one of various electronic devices constituting computer network, one of various electronic devices constituting telecommunication network, RFID, or one of various user devices constituting a home network.

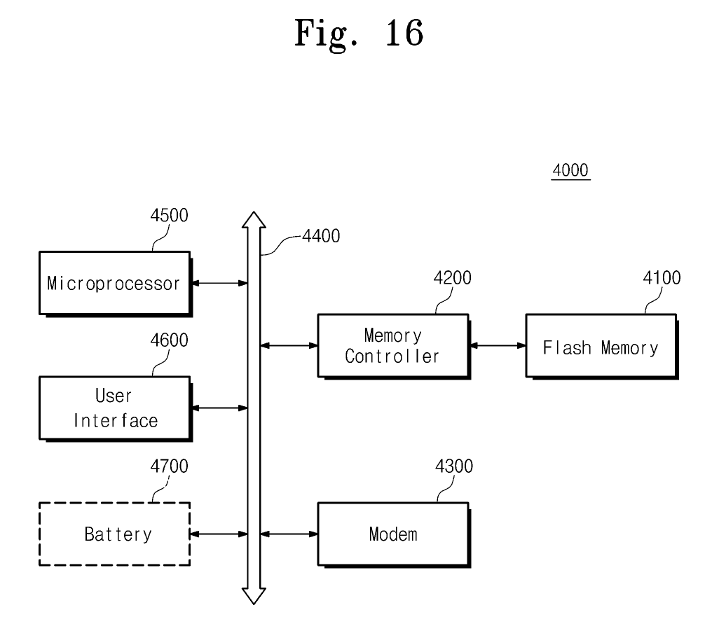

FIG. 15 is a block diagram illustrating a data storage device according to still another embodiment. Referring to FIG. 15, a data storage device 3000 may include a flash memory 3100 and a flash controller 3200. The flash controller 3200 may control the flash memory 3100 in response to control signals received from the outside of the data storage device 3000.

The flash memory 3100 may be configured the same as that illustrated in FIG. 1. The flash memory 3100 may be configured to have one of a stack flash structure having arrays stacked in multi-layer, a source-drain free flash structure, a pin-type flash structure, and a three-dimensional flash structure. The flash memory 3100 may be configured to apply both a dual pulse program manner and a 2-step verification manner to all target states.

The data storage device 3000 may be a memory card device, an SSD device, a multimedia card device, an SD device, a memory stick device, a HDD device, a hybrid drive device, or a USB flash device. For example, the data storage device 3000 may be a card satisfying the industrial standard for using a user device such as a digital camera, a personal computer, etc.

FIG. 16 is a diagram schematically illustrating a computing system including a flash memory device according to an example embodiment. Referring to FIG. 16, a computing system 4000 may include a flash memory device 4100, a memory controller 4200, a modem 4300 such as a baseband chipset, a microprocessor 4500, and a user interface. The elements 4200, 4300, 4500, and 4600 may be electrically connected with a bus 4400.

The flash memory device 4100 illustrated in FIG. 16 may be configured the same as that illustrated in FIG. 1. The flash memory device 4100 may be configured to have one of a stack flash structure having arrays stacked in multi-layer, a source-drain free flash structure, a pin-type flash structure, and a three-dimensional flash structure. The flash memory device 4100 may be configured to apply both a dual pulse program manner and a 2-step verification manner to all target states.

In the event that the computing system 4000 is a mobile device, it may further comprise a battery 4700 for powering the computing system 4000. Although not shown, the computing system 4000 may further include an application chipset, a camera image processor (CIS), a mobile DRAM, and the like. The memory controller 4200 and the flash memory device 4100 may constitute a solid state drive/drive (SSD) which uses a nonvolatile memory to store data, for example.

In some embodiments, a nonvolatile memory device and/or a memory controller may be packed by various types of packages such as PoP (Package on Package), Ball grid arrays (BGAs), Chip scale packages (CSPs), Plastic Leaded Chip Carrier (PLCC), Plastic Dual In-Line Package (PDI2P), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

Accordingly, it will be understood by one of ordinary skill in the art that various changes in form and details may be made therein without departing from the spirit and scope of the following claims.

What is claimed is:

1. A program method of a nonvolatile memory device comprising:
applying a first program voltage to a word line of a memory cell;
verifying a variation of a threshold voltage of the memory cell; and
applying a second program voltage to the word line of the memory cell when a threshold voltage of the memory cell is higher than a reference level, the second program voltage being lower in level than the first program voltage.

2. The program method of claim 1, wherein the applying a first program voltage and the verifying are performed at a first program loop and the applying a second program voltage is performed at asecond program loop.

3. The program method of claim 2, wherein the first program voltage is a pulse having a high level from among a dual-pulse applied at the first program loop and the second program voltage is a pulse having a low level from among a dual-pulse applied at the second program loop.

4. The program method of claim 1, wherein when the first program voltage is applied to the word line, a bit line forcing voltage is supplied to a bit line of the memory cell.

5. The program method of claim 4, wherein when the second program voltage is applied to the word line, 0V is supplied to a bit line of the memory cell.

6. The program method of claim 1, further comprising:
verifying whether a threshold voltage of the memory cell is over a target level higher than the reference level.

7. The program method of claim 6, wherein if the threshold voltage of the memory cell is higher than the reference level and lower than the target level, 0V is supplied to a bit line of the memory cell when the second program voltage is applied to the word line.

8. The program method of claim 7, wherein if the threshold voltage of the memory cell is identical to or higher than the target level, a program inhibition voltage is supplied to a bit line of the memory cell.

9. A program method of a nonvolatile memory device, the program method comprising:
performing a plurality of program loops on memory cells in order to program the memory cells;
applying a plurality of dual pulses to a word line of the memory cells, each of the plurality of dual pulses including a first pulse and a second pulse having a greater level than the first pulse such that the plurality of dual pulses includes a plurality of first pulses and a plurality of second pulses;
during a period of at least one second pulse of the plurality of second pulses, applying a first bit line program voltage to a bit line coupled to a first memory cell of the memory cells if the first memory cell has a threshold voltage smaller than a first verify voltage, thereby programming the first memory cell; and
during a period of at least one first pulse of the plurality of first pulses, applying a second bit line program voltage smaller than the first bit line program voltage to a bit line coupled to the first memory cell if the first memory cell has a threshold voltage greater than the first verify voltage and smaller than a second verify voltage, thereby programming the first memory cell.

10. The program method of claim 9, wherein the applying a first dual pulse of the plurality of dual pulses is performed for a first program loop of the plurality of program loops.

11. The program method of claim 10, further comprising:
before the first program loop, verifying a threshold voltage of the first memory cell using the first verify voltage and the second verify voltage.

12. The program method of claim 9, further comprising:
during a period of the at least one first pulse of the plurality of first pulses, applying a bit line inhibition voltage to a bit line coupled to the first memory cell if the first memory cell has a threshold voltage smaller than the first verify voltage, thereby not programming the first memory cell; and
during a period of the at least one second pulse of the plurality of second pulses, applying the bit line inhibition voltage to a bit line coupled to the first memory cell if the first memory cell has a threshold voltage greater than the first verify voltage and smaller than the second verify voltage, thereby not programming the first memory cell,
wherein the bit line inhibition voltage is greater than the first bit line program voltage.

13. The program method of claim 12, wherein the second bit line program voltage is 0V.

14. The program method of claim 9, further comprising:
after the applying a first bit line program voltage, verifying whether a threshold voltage of the first memory cell reaches the first verify voltage or the second verify voltage; and
after the applying a second bit line program voltage, verifying whether a threshold voltage of the first memory cell reaches the second verify voltage.

15. The program method of claim 9, wherein if the threshold voltage of the first memory cell is identical to or higher than the second verify voltage, a program inhibition voltage is supplied to the bit line of the first memory cell, the program inhibition voltage being a power supply voltage.

16. A method of programming a nonvolatile memory device comprising memory cells coupled to word lines and bit lines, each of the memory cells to be programmed to one of a plurality of program states, the method comprising:
verifying a threshold voltage of first memory cells of the memory cells using a first verify voltage and a second verify voltage greater than the first verify voltage;
applying a plurality of dual pulses to a word line of the first memory cells until programming of the first memory cells to a specific target program state among the plurality of program states completes, each of the plurality of dual pulses including a first pulse and a second pulse having a higher level than the first pulse and being incremented by a step voltage;
during a period of at least one of second pulses of the plurality of dual pulses, applying a first bit line program voltage to bit lines coupled to a first set of memory cells of the first memory cells until a threshold voltage of the first set of memory cells reaches a level equal to or greater than a first verify voltage, the first one or more memory cells having a threshold voltage smaller than the first verify voltage resulting from the verifying; and
during a period of at least one of first pulses of the plurality of dual pulses, applying a second bit line program voltage smaller than the first bit line program voltage to bit lines coupled to a second set of memory cells of the first memory cells until a threshold voltage of the second one or more memory cells reaches a level equal to or greater than the second verify voltage, the second set of memory cells having a threshold voltage greater than the first verify voltage and smaller than the second verify voltage resulting from the verifying.

17. The method of claim 16, further comprising:
during a period of at least one of first pulses of the plurality of dual pulses, applying a program inhibition voltage to bit lines coupled to the first set of memory cells; and
during a period of at least one of second pulses of the plurality of dual pulses, applying the program inhibition voltage to bit lines coupled to the second set of memory cells,
wherein the program inhibition voltage is greater than the first bit line program voltage.

18. The method of claim 17, wherein the second bit line program voltage is 0V and the program inhibition voltage is a power supply voltage.

19. The method of claim 18, further comprising:
applying the program inhibition voltage to bit lines coupled to the first memory cells when a threshold voltage of the first memory cells is equal to or greater than the second verify voltage.

20. The method of claim 16, wherein the plurality of program states include a first program state P1, a second program state P2, and a third program state P3 according to a distribution of threshold voltages of the memory cells,
wherein a threshold voltage associated with the second program state P2 is greater than a threshold voltage associated with the first program state P1 and is smaller than a threshold voltage associated with the third program state P3, and
wherein the specific target program state is the second program state P2.
